(19) United States
(12) Patent Application Publication
(10) Pub. No.: US 2013/0056362 A1
(43) Pub. Date: Mar. 7, 2013

(54) MANUFACTURE METHOD OF BUILDUP CIRCUIT BOARD

(71) Applicant: C. Uyemura and Co., Ltd., Osaka (JP)

(72) Inventors: Shinji TACHIBANA, Osaka (JP); Naoyuki OMURA, Osaka (JP); Tomohiro KAWASE, Osaka (JP); Toshihisa ISONO, Osaka (JP); Teruyuki HOTTA, Osaka (JP)

(73) Assignee: C. UYEMURA AND CO., LTD., Osaka (JP)

(21) Appl. No.: 13/666,357

(22) Filed: Nov. 1, 2012

Related U.S. Application Data
(62) Division of application No. 12/233,372, filed on Sep. 18, 2008.

(30) Foreign Application Priority Data
Sep. 19, 2007 (JP) 2007-241833

(51) Int. Cl. H05K 3/46

(52) U.S. Cl. 205/125

(57) ABSTRACT

A manufacturing method of a buildup circuit board includes forming a wiring layer on an organic polymer insulating layer by copper electroplating and building up other organic polymer insulating layer on the wiring layer, wherein in a final step of the copper electroplating, a surface of the wiring layer is roughened by copper electroplating and the organic polymer insulating layer is formed directly on the roughened surface of the wiring layer. According to the invention, a specific etching step that is essential for enhancing adhesion between the organic polymer insulating layer and the wiring layer can be omitted and no expensive etching apparatus is necessary, thus being good in economy. In addition, if various types of copper sulfate plating baths containing different types of additives used for via fill plating are used as they are, irregularities on the surface can be made in various forms and roughnesses. Thus, it is necessary to select a specific type of etching solution depending on film characteristics ascribed to types of additives. Moreover, it is easy to form surface irregularities in conformity with the type of material and physical properties of the organic polymer insulating layer being built up.

### BACKGROUND OF THE INVENTION

1. Field of the Invention

This invention relates to a manufacturing method of a buildup circuit board.

2. Description of the Related Art

There is known a method of manufacturing a laminated circuit board called buildup method. In a method called semi-additive method, as shown in FIGS. 3A to 3J, for example, an inner-layer wiring 2a is formed on an inner-layer resin 1, after which an insulating resin 11a is attached to the inner-layer wiring 2a (FIG. 3A), and a via hole 3 is formed in the insulating resin 11a by laser irradiation. This via hole 3 and the insulating resin 11a are subjected, on the surfaces thereof, to desmear treatment (FIG. 3B), followed by deposition of a catalyst 21 and electroless copper plating (FIG. 3D). A plating resist 4 is provided on the electroless copper plating film 22 (FIG. 3E) and a pattern not covered with the resist is subjected to copper electroplating to form an inner-layer wiring (copper electroplating film) 2b (FIG. 3F). Next, the resist 4 is removed (FIG. 3G), after which the electroless copper plating film 22 is removed along with the catalyst 21 (FIG. 3H), followed by repeating the attaching step of the insulating resin 11b (FIG. 3J) so as to further form an upper-layer wiring.

In a method called subtractive method, as shown in FIGS. 4A to 4J, for example, an inner-layer wiring 2a is formed on an inner-layer resin 1, after which a copper foil-clad insulating film (RCC resin) 11a is attached to the inner-layer wiring 2a (FIG. 4A), followed by formation of a via hole 3 in the insulating resin 11a by laser irradiation. This via hole 3 and the insulating resin 11a are subjected, on the surfaces thereof, to desmear treatment (4B), followed by deposition of a catalyst 21 (FIG. 4C) and electroless copper plating (FIG. 4D), and further by formation of a copper electroplating film 2b on the electroless copper plating film 22 by copper electroplating (FIG. 4E). Next, an etching resist is applied onto the copper electroplating film 2b (FIG. 4F), the copper electroplating film 2b at a portion not covered with the resist is removed along with the electroless copper plating film 22 and the catalyst 21 (FIG. 4G) to form an inner-layer wiring (copper electroplating film) 2b and the resist 4 is also removed (FIG. 4H). Thereafter, the step of attaching a copper foil clad insulating resin (RCC resin) 11b is repeated (FIG. 4J) so as to further form an upper-layer wiring.

However, with the conventional copper electroplating techniques set out above, no irregularities exist on the surface of the copper electroplating film 2b, for which the copper electroplating film 2b has to be formed with irregularities 20 (FIG. 3I or 4I) on the surface thereof by electrolytic etching or etching treatment as set forth in JP-A 2000-282265 for the purpose of enhancing adhesion to an insulating resin. Thereafter, the insulating resin 11b is formed.

However, in order to make irregularities on the surface by etching treatment, it has been necessary to use a specific type of expensive etching apparatus. The characteristics of a copper electroplating film changes depending on the types of additives used in a copper sulfate plating bath used for copper electroplating. Unless an etching solution is changed accordingly, satisfactory irregularities cannot be formed on the film surface, thus resulting in the complicated selection of etching solutions.

It will be noted that mention is made, as prior art documents, of JP-A 2000-282265, JP-T 2006-526890, JP-A 2000-68644, JP-A 2002-134918, JP-A 2000-44799, JP-A 2001-274549, JP-A 3-204992, JP-B 7-19959, JP-A 5-335744 and JP-A 2001-210932.

### SUMMARY OF THE INVENTION

Under these circumstances set out above, the invention has for its object the provision of a method for efficiently manufacturing a buildup circuit board by a simple process while keeping good adhesion between a wiring layer and an insulating layer.

In order to achieve the above object, we have made intensive studies on the manufacture of a buildup circuit board wherein an organic polymer insulating (insulating resin) layer is built up in good adhesion to a wiring layer without carrying out an etching step that has been accepted as essential after formation of a wiring layer (an inner-layer wiring). As a result, it has been found that when a film having surface irregularities, which has never been utilized up to now for the reason that film characteristics would be worsened, is used in combination with conventional plating such as of a via fill, irregularities can be formed on a copper electroplating film during the course of a copper electroplating process for forming a layer. In this way, a specific etching process can be omitted. It has also be found that if irregularities are formed by a method wherein plating conditions are changed in a copper electroplating process, e.g. while using the preceding copper electroplating process as it is, the conditions alone are changed in a final step of the copper electroplating process so as to make a roughened surface, or by a method wherein copper electroplating is carried out by changing a type of copper electroplating bath and plating conditions to those capable of forming a roughened surface, surface irregularities can be controlled in various forms with different roughnesses (surface roughness Ra). Accordingly, while keeping plating characteristics of a body layer occupying most of the wiring layer, good adhesion between the wiring layer and the organic polymer insulating layer is ensured, thereby efficiently manufacturing a buildup circuit board by a simple procedure. The invention has been accomplished based on the above findings.

More particularly, the invention contemplates to provide the following manufacturing method of a buildup circuit board.

A manufacturing method of a buildup circuit board includes the steps of forming a wiring layer on an organic polymer insulating layer by copper electroplating and further building up other organic polymer insulating layer on the wiring layer, characterized in that a surface of the wiring layer is roughened on the surface thereof in a final step of the copper electroplating and said organic polymer insulating film is built up directly on the roughened surface of the wiring layer.

Especially, the final step of the copper electroplating for forming the roughened surface should preferably be a copper electroplating step wherein a reverse electrolysis pulse is applied.

The copper electroplating for forming the roughened surface in the final step thereof is preferably carried out in a copper electroplating bath that contains a sulfur-containing compound and a nitrogen-containing compound and is free of a polyether compound, or in a copper electroplating bath that contains a sulfur and nitrogen-containing compound and is free of a polyether compound.

Further, the roughened surface should preferably have a surface roughness Ra of 0.01 to 1 μm.

According to the invention, a specific etching step, which has been considered essential so as to enhance adhesion between the organic polymer insulating layer and the wiring layer, can be omitted and there is no need for using an expensive etching apparatus, thus being good in economy. Although surface irregularities in various forms with different roughnesses can be formed when using, as they are, various types of copper sulfate plating baths containing various types of additives employed in via fill plating, it is unnecessary to select a specific type of etching solution depending on the film characteristics ascribed to types of additives. It is easy to form surface irregularities in conformity with the type of material and physical properties of an organic polymer insulating layer to be built up.

### BRIEF DESCRIPTION OF THE DRAWINGS

FIGS. 1A to 1J are, respectively, an illustrative view showing an example of a step of a manufacturing method of a buildup circuit board (i.e. a semi-additive method) including a copper electroplating step according to the invention.

FIGS. 2A to 2J are, respectively, an illustrative view showing an example of a step of a manufacturing method of a buildup circuit board (i.e. a subtractive method) including a copper electroplating step according to the invention.

FIGS. 3A to 3J are, respectively, an illustrative view showing a step of a conventional manufacturing method of a buildup circuit board (i.e. a semi-additive method).

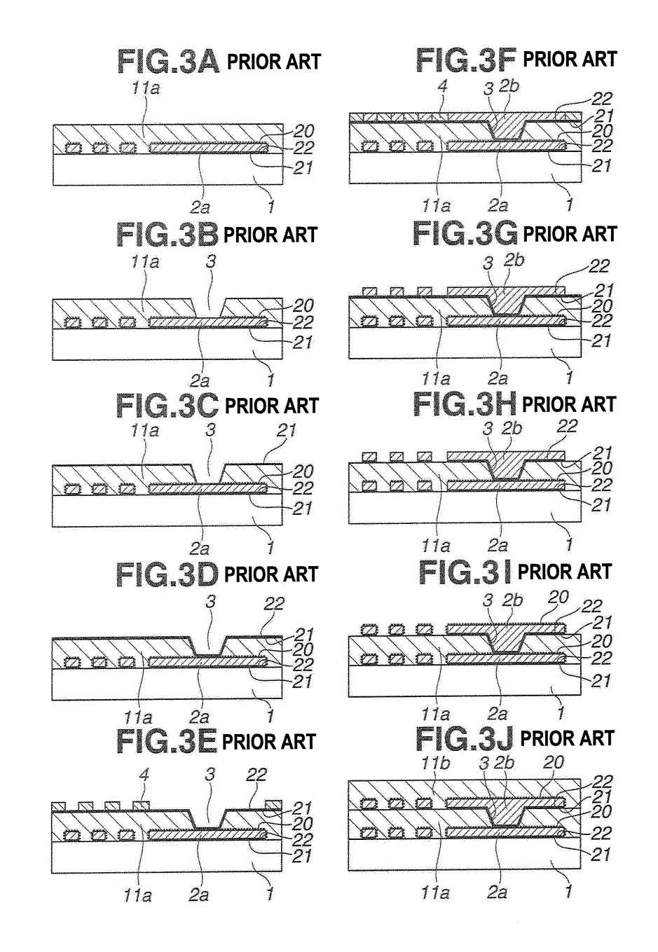

FIGS. 4A to 4J are, respectively, an illustrative view showing a step of a conventional manufacturing method of a buildup circuit board (i.e. a subtractive method).

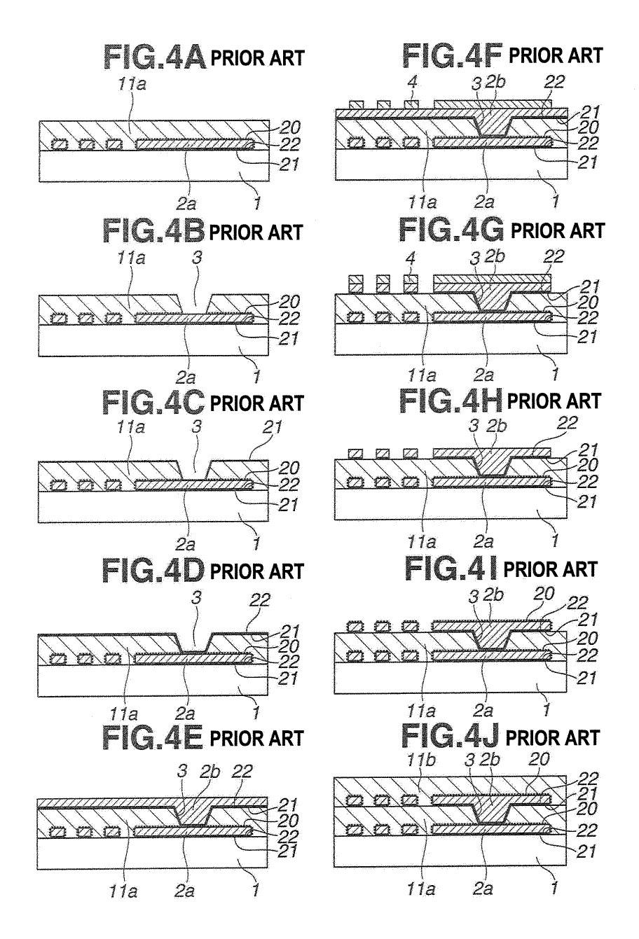

FIGS. 5A to 5F are, respectively, scanning electron microscope images of surfaces of copper electroplating films formed in Experimental Examples 1, 2, 3, 4, 7 and 8.

FIG. 6 is a schematic view showing a shape and size of a test piece used for measuring physical properties of films in Experimental Examples 13, 14 and Comparative Experimental Examples 1 to 3.

### DETAILED DESCRIPTION OF THE PREFERRED EMBODIMENTS

The invention is directed to a manufacturing method of a buildup circuit board, which includes the steps of forming a wiring layer on an organic polymer insulating layer (generally, a layer of an insulating layer such as of an epoxy resin or the like) by copper electroplating and further building up other organic polymer insulating layer on the wiring layer. In the practice of the invention, in a final step of the copper electroplating through which the wiring layer (or a copper electroplating film for forming the wiring layer) is formed, the surface of the wiring layer is roughened by the copper electroplating and the organic polymer insulating layer is directly (i.e. without interposition of other layer) built up on the roughened surface of the wiring layer.

In the copper electroplating of the invention, most of the wiring layer is formed by copper electroplating which is ordinarily applied to in the manufacture of a buildup circuit board. At a final stage (final step) of this copper electroplating process, copper electroplating for forming a wiring layer whose surface is roughened is applied.

In particular, such a method includes initially forming a wiring layer by a copper electroplating using a direct current, and applying a reverse electrolysis pulse current in the final stage (final step), thereby enabling the surface of the wiring layer to be roughened (this method may be sometimes called reverse electrolysis pulse process).

As a copper electroplating bath (first copper electroplating bath) used in this case, a known copper electroplating bath applied to the manufacture of a buildup circuit board (e.g. a copper sulfate plating bath for via fill or damascene) can be used. To this end, there can be used a bath containing, for example, 10 to 65 g/liter of copper sulfate as copper ions (Cu²⁺), 20 to 250 g/liter of sulfuric acid, 20 to 100 mg of chloride ions (Cl⁻) and organic additives used in a copper sulfate bath for via fill or damascene.

The organic additives may be, for example, one or a plurality of sulfur-containing compounds represented by the following formulas (1) to (3) and are preferably used in amounts of 0.01 to 100 mg/liter, more preferably 0.1 to 50 mg/liter.

R₁—S—(CH₂)ₙ—(O)ₚ—SO₃M (1)

(R₂)₂N—CSS—(CH₂)ₙ—(CHOH)ₚ—(CH₂)ₙ—(O)ₚ—SO₃M (2)

R₂—O—CSS—(CH₂)ₙ—(CHOH)ₚ—(CH₂)ₙ—(O)ₚ—SO₃M (3)

wherein R₁ represents a hydrogen atom or a group represented by —(S)ₘ—(CH₂)ₙ—(O)ₚ—SO₃M, R₂'s independently represent an alkyl group having 1 to 5 carbon atoms, M represents a hydrogen atom or an alkali metal, m is 0 or 1, n is an integer of 1 to 8, and p is 0 or 1.

The polyethers include compounds containing polyalkylene glycol having not smaller than four —O— linkages. Specific examples include polyethylene glycol, polypropylene glycol and copolymers thereof, polyethylene glycol fatty acid esters, polyethylene glycol alkyl ethers and the like. These polyether compounds are preferably present in an amount of 10 to 5000 mg/liter, more preferably 100 to 1000 mg/liter.

Further, the nitrogen-containing compounds include polyethyleneimine and derivatives thereof, polyvinyl imidazole and derivatives thereof, polyvinyl alkylimidazoles and derivatives thereof, copolymers of vinyl pyrrolidone and vinyl alkylimidazoles or derivatives thereof, and dyes such as janus green B. The amount is preferably in the range of 0.001 to 500 mg/liter, more preferably 0.01 to 100 mg/liter.

It will be noted that the pH of the copper sulfate plating bath is generally at 2 or below.

In the practice of the invention, the anode used is either a soluble anode or insoluble anode and an object to be plated is provided as a cathode, under which copper electroplating is carried out on the object. With the reverse electrolysis pulse process, copper electroplating is initially carried out by use of a direct current. In this case, the cathode current density is generally in the range of 0.5 to 7 A/dm², preferably 1 to 5 A/dm².

On the other hand, with the reverse electrolysis pulse applied to the final stage of the copper electroplating process, it is preferred that a positive (plating side) current (cathode current density) Ai and a negative (removing side) current (cathode current density) Bi are such that Bi ranges 0.5 to 7 A/dm², preferably 1 to 5 A/dm² and Ai/Bi=½ to ⅕ and that a positive (plating side) pulse time At and a negative (removing side) pulse Bt are such that Bt is in the range of 1.0 to 10 ms, within which it is preferred that At/Bt=5 to 50.

The plating time applied with the reverse electrolysis pulse preferably ranges from 1 to 10 minutes and is preferably at ⅓ to 1/100, more preferably ¼ to 1/75 and most preferably ⅕ to 1/50 relative to the total copper electroplating time. When the plating time applied with a reverse electrolysis pulse is lower than the above-defined range, there is concern that satisfactory adhesion cannot be obtained. Over the above range, there is also concern that the characteristics, particularly, tensile strength and a percentage elongation, of a copper electroplating film are worsened.

The wiring layer is first formed by use of a direct current by copper electroplating using a known copper electroplating bath (e.g. a copper sulfate plating bath such as for a via fill or damascene) employed in the manufacture of a buildup circuit board (more particularly, under plating conditions similar to those using the first copper electroplating and a direct current exemplified in the above-stated reverse electrolysis pulse technique). At a final stage (final step), copper electroplating using a direct current and a copper electroplating bath that contains, as an organic additive, a sulfur-containing compound and a nitrogen-containing compound and is free of a polyether compound or a copper electroplating bath (i.e. a second copper electroplating bath) that contains a sulfur and nitrogen-containing compound and is free of a polyether compound is carried out to form a roughened surface of the wiring layer (this method may be sometimes called dual plating bath technique).

In this case, the copper electroplating bath (second copper electroplating bath) used to form the roughened surface of the wiring layer may be one which includes, for example, 10 to 65 g/liter of copper sulfate as copper ions (Cu²⁺), 20 to 250 g/liter of sulfuric acid and 20 to 100 mg/liter of chloride ions (Cl⁻). The bath further includes organic additives which are used in a copper sulfate plating bath for via fill or damascene and which are made of a sulfur-containing compound and a nitrogen-containing compound and are free of a polyether compound, or are made of a sulfur and nitrogen-containing compound and are free of a polyether compound.

In this case, the sulfur-containing compound, nitrogen-containing compound and polyether compound, respectively, those mentioned with respect to the first copper electroplating bath exemplified in the reverse electrolysis pulse technique, and the concentrations in the plating bath of the sulfur containing-compound and nitrogen-containing compound are similar to those defined hereinbefore.

On the other hand, the sulfur and nitrogen-containing compounds include thiazole and derivatives thereof, thiazoline and derivatives thereof, benzothiazoline and derivatives thereof, rhodanine and derivatives thereof, thiourea and derivatives thereof, benzothiazole and derivatives thereof, and dyes such as methylene blue, titanium yellow and the like, and are used in an amount of 0.001 to 500 mg/liter, preferably 0.01 to 100 mg/liter.

In the copper electroplating using this second copper electroplating bath, a cathode current density is generally in the range of 0.5 to 7 A/dm², preferably 1 to 5 A/dm² in the form of a direct current. As set out in the foregoing reverse electrolysis pulse technique, a reverse electrolysis pulse may also be applied.

The plating time of the copper electroplating, to which the second copper electroplating bath is applied, is preferably from about 1 to 10 minutes and is in the range of ⅓ to 1/100, preferably ¼ to 1/75 and more preferably ⅕ to 1/50 of the total copper electroplating time.

It will be noted that in either of the reverse electrolysis pulse technique or the dual plating bath technique, the pH of the copper sulfate plating bath is generally at 2 or below. The plating temperature is generally at 20 to 30° C. The copper electroplating for forming the roughened surface (i.e. plating by reverse electrolysis pulse or plating using the second copper electroplating bath) may be performed continuously from the preceding copper electroplating (i.e. plating by a direct current using the first copper electroplating bath) or may be performed after known cleaning and surface oxide film-removing treatments.

It will be noted that the thickness of the copper electroplating film (wiring layer) is generally at 5 to 40 μm, in which not less than 1/50, preferably not less than 1/20 and not larger than ½, preferably not larger than ⅓ of the film thickness is preferably one that is formed by the copper electroplating for forming the roughened surface. Especially, the thickness of the film formed by the copper electroplating for forming the roughened surface is at not less than 0.1 μm, preferably not less than 0.2 μm and more preferably not less than 0.5 μm and at less than 5 μm, preferably not larger than 4 μm and more preferably not larger than 3 μm. If the thickness formed by the copper electroplating for the roughened surface is lower than the above range, there is concern that satisfactory adhesion cannot be obtained. Over the above range, there is also concern that the physical properties, particularly, tensile strength and a percentage elongation, of the copper electroplating film are worsened.

Next, an instance of a manufacturing method of a buildup circuit board to which the method of forming a wiring layer by copper electroplating according to the invention is applied is illustrated with reference to the accompanying drawings.

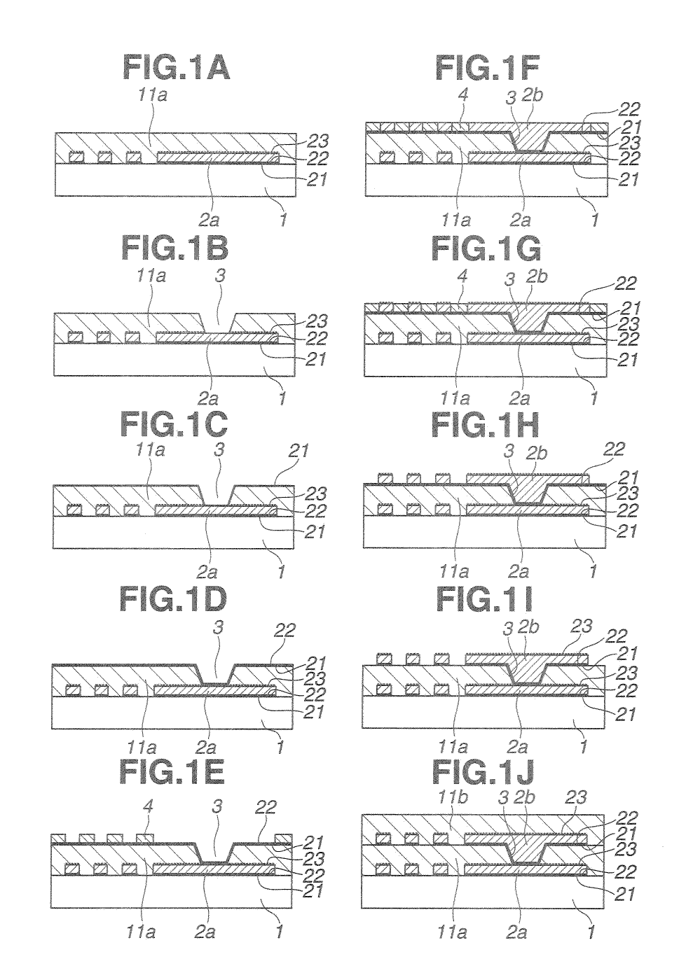

FIGS. 1A to 1J, respectively, show an instance of a method of manufacturing a buildup circuit board according to a semi-additive method. In this method, an inner-layer wiring 2a is formed on an inner-layer resin 1 in a preceding step, after which an insulating resin 11a is attached to the inner-layer wiring 2a (FIG. 1A). A via hole 3 is formed in the insulating resin 11a by laser irradiation, and the via hole 3 and the insulating resin 11a are subjected to desmear treatment on the surfaces thereof (FIG. 1B), followed by deposition of a catalyst 21 (FIG. 1C) and electroless copper plating (FIG. 1D). A plating resist 4 is provided on the electroless copper plating film (FIG. 1E). The resulting pattern non-covered with the resist is subjected to copper electroplating treatment to form an inner-layer wiring (copper electroplating film) 2b (FIG. 1F). At this stage, copper electroplating by either a reverse electrolysis pulse technique or a dual plating bath technique according to the invention is applied so that the surface of the wiring layer (copper electroplating film) is formed as a roughened surface 23 (FIG. 1G). Next, the resist 4 is removed (FIG. 1H), after which the electroless copper plating film 22 is removed together with the catalyst 21 (FIG. 1I). Moreover, the step of attaching the insulating resin 11b is repeated (FIG. 1J) so as to further form an upper-layer wiring. In this method, the via hole and the surface pattern material (i.e. an electroless copper plating film exposed through the patterned resist) are simultaneously copper-electroplated.

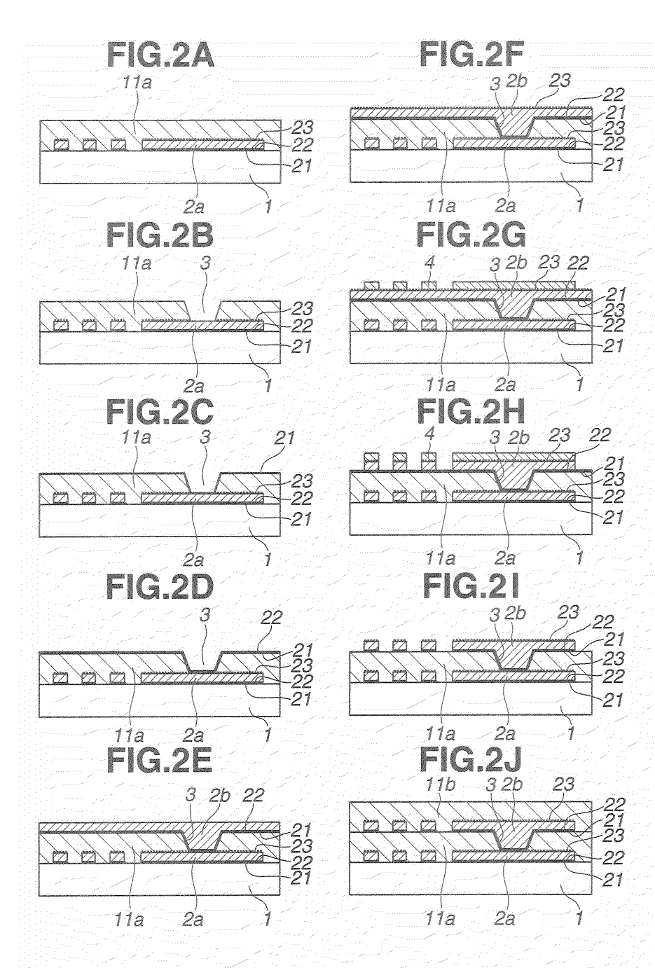

FIGS. 2A to 2J show another instance of a manufacturing method of a buildup circuit board according to a subtractive method. In this method, an inner-layer wiring 2a is formed on an inner-layer resin 1 in a preceding step, after which an insulating resin 11a attached with a copper foil (RCC resin) is attached on the inner-layer wiring 2a (FIG. 2A), followed by laser irradiation to form a via hole 3 in the insulating resin 11a. This via hole 3 and the insulating resin 11a are subjected to desmear treatment on the surfaces thereof (FIG. 2B), followed by deposition of a catalyst 21 (FIG. 2C) and electroless copper plating (FIG. 2D). A copper electroplating film 2b is formed on the electroless copper plating film 22 by copper electroplating treatment (FIG. 2E). At this stage, copper electroplating by a reverse electrolysis pulse technique or a dual plating bath technique according to the invention is subsequently performed so that the surface of the wiring layer (copper electroplating film) was roughened as roughened surface 23 (FIG. 2F). Next, an etching resist 4 is formed on the copper electroplating film 2b (FIG. 2G), and the copper electroplating film 2b at portions non-covered with the resist is removed along with the electroless copper plating film 22 and the copper foil on the surfaces of the catalyst 21 and the insulating resin 11a (FIG. 2H) to form an inner-layer wiring (copper electroplating film) 2b, and the resist 4 is removed (FIG. 2I). Further, the step of attaching a copper foil-attached insulating resin (RCC resin) 11b is repeated (FIG. 2J) so as to further form an upper-layer wiring. In this method, the entirety of the board surface is copper-electroplated along with the via hole, after which the copper coating on the board surface is patterned.

It will be noted that with respect to treatments other than the copper electroplating, any known techniques may be adopted and, for example, the following techniques may be used.

### (1) Formation of a Via Hole

Any known via hole-making method may be adopted. For instance, a via hole can be made by laser irradiation. In addition, there may be adopted those methods set forth in JP-A 2000-68644, JP-A 2002-134918, JP-A 2000-44799 and the like.

### (2) Desmear Treatment

Any known desmear treatment can be adopted. For instance, a swelling treatment is carried out, followed by smear removal with a permanganic acid solution and neutralization. To this end, methods set forth in JP-A 2001-274549, JP-A 3-204992, JP-B 7-19959 and the like.

### (3) Pretreatment

Any known pretreatments may be adopted. For instance, the pretreatment can be carried out by any of treatments including a cleaner treatment using a solution mainly composed of a nonionic surface active agent, a conditioner treatment capable of promoting deposition of a catalyst by use of a solution mainly composed of a cationic surface active agent, a soft etching or microetching treatment wherein an acidic solution is used to remove a surface oxide film, and a combination of cleaner/conditioner treatments using a single mixture of the above-indicated cleaner solution and conditioner solution.

### (4) Catalyst-Depositing Treatment

Any known catalyst-depositing treatment may be adopted. For instance, there can be used a catalyst deposition treatment using a tin-palladium colloid, a catalyst deposition treatment using a sensitizing activator technique, and a catalyst deposition treatment using an alkali catalyst/accelerator technique.

### (5) Electroless Copper Plating Treatment

Any known electroless copper plating treatment may be adopted. For instance, an alkaline bath, a neutral bath or the like can be used and a reducing agent used is not critical in type.

### (6) Resist Formation

Any known resist formation technique may be adopted. For instance, a resist pattern can be formed using a dry film made of a known resin in such a way as to form a surface pattern on the film to be masked. The resist may be either of a positive type or a negative type, and a resin used is not critical in type.

### (7) Resist Removing Treatment

Any known resist removing treatment may be adopted. For instance, an alkaline solution is used to remove a dry film (resist) by dissolution. The alkaline solution includes a sodium hydroxide solution, a potassium hydroxide solution or the like.

### (8) Electroless Copper Film Removing Treatment

Any known electroless copper film removing treatment may be adopted. For example, in a semi-additive method, an electroless copper plating film, on which no copper electroplating film is built up, is exposed. This electroless copper plating film can be removed with an acidic solution. The acidic solution includes an iron (II) chloride aqueous solution, an aqueous solution of a sulfuric acid/hydrogen peroxide mixture or the like.

### (9) Copper Electroplating Film Removing Treatment

Any known copper electroplating film-removing treatment may be adopted. For example, although a copper electroplating film, on which no resist is built up, is exposed in the subtractive technique, this copper electroplating film can be removed along with an electroless copper plating film by means, for example, of a known acidic solution such as a sulfuric acid/hydrogen peroxide aqueous solution, a cupric chloride aqueous solution or the like.

It will be noted that any known direct plating techniques may be adopted. In the direct plating technique, copper electroplating is directly performed after treatments with a Sn—Pd colloid, a Pd catalyst, a carbon catalyst and a conductive resin. The direct plating technique is especially effective for the subtractive method. In this connection, the above step (5) and the steps (3) and (4) may be omitted. Instead of the above steps (3) and (4), a sand blasting method as set out in JP-A 5-335744 may be adopted. Moreover, prior to the copper electroplating step, the circuit board may be preliminarily dipped into a solution containing one or more organic additives for via fill, after which copper electroplating is performed.

By the above-stated copper electroplating according to the method of the invention, the resulting copper electroplating film (wiring layer) has a surface roughness (Ra) of not less than 0.01 μm, preferably not less than 0.02 μm, more preferably not less than 0.025 μm, much more preferably not less than 0.03 μm and most preferably not less than 0.05 μm, and also of not larger than 1 μm, preferably not larger than 0.5 μm, more preferably not larger than 0.1 μm, much more preferably less than 0.1 μm and most preferably not larger than 0.09 μm. If the roughness is lower than the above range, adhesion with a builtup resin becomes worsened along with concern that satisfactory surface irregularities are not left through the removal treatment of electroless copper film in the subtractive method. Over the above range, surface irregular portions becomes embrittled, with concern that adhesion with a builtup resin becomes worsened. If necessary, a known cleaning treatment may be performed on the wiring layer surface which has been roughened. Thereafter, an organic polymer insulating layer is built up directly on the surface according to a known procedure (e.g. coating and curing of a resin or a lamination of a resin sheet or the like) applied in the manufacture of a buildup circuit board, by which there can be obtained strong adhesion between the wiring layer and the insulating resin in the built-up circuit board only by the copper electroplating step without application of a conventional etching step.

It will be noted that in FIGS. 1A to 1j and 2A to 2J, the wiring layer illustrated is one wherein two layers are formed, which should not be construed as limitation thereof. Depending on the purpose in end use, the wiring layer may be formed on one side or both sides and may be formed as one layer or three or more layers.

### EXAMPLES

The invention is more particularly described by way of Experimental Examples and Examples, which should not be construed as limiting the invention thereto. Comparative Examples are also shown.

### Experimental Examples 1 to 6

A copper electroplating film was formed on an object to be plated, i.e. an FR-4 substrate, according to treating steps indicated in the following Tables 1 to 3. The copper electroplating [step (C-6)] was carried out under the following conditions 1-1 (primary plating) and conditions 2-1 (secondary plating) in this order.

TABLE 1

| | | | Temperature | Time |
|---|---|---|---|---|
| Treatment | | Chemicals used | (° C.) | (minutes) |
| (A-1) | Swelling | DEC-501*¹: | 80 | 10 |
| | | 500 ml/liter | | |
| (A-2) | Hot-water washing | | 40 | 1 |
| (A-3) | Water washing | | Room | 2 |
| | | | temperature | |
| (A-4) | Roughening | DES-502A*¹: | 80 | 15 |
| | | 100 ml/liter | | |
| | | DES-502B*¹: | | |
| | | 140 ml/liter | | |
| (A-5) | Recovery | | Room | 0.5 |
| | | | temperature | |
| (A-6) | Water washing | | Room | 2 |
| | | | temperature | |
| (A-7) | Neutralization | DEN-503H*¹: | Room | 7 |
| | | 150 ml/liter | temperature | |
| (A-8) | Water washing | | Room | 2 |
| | | | temperature | |
| (A-9) | Drying | | | |

*¹made by Taiwan Uyemura Co., Ltd.

TABLE 2

| | | | Temperature | Time |
|---|---|---|---|---|
| Treatment | | Chemicals used | (° C.) | (minutes) |
| (B-1) | Cleaner/conditioner | THRU-CUP ACL-009*²: 50 ml/liter | 50 | 5 |
| (B-2) | Hot water washing | | 40 | 1 |
| (B-3) | Water washing | | Room | 1 |
| | | | temperature | |
| (B-4) | Soft etching | Sodium persulfate: | 25 | 1 |
| | | 200 g/liter | | |
| | | Sulfuric acid: 50 g/liter | | |
| (B-5) | Water washing | | Room | 1 |
| | | | temperature | |
| (B-6) | Acid washing | Sulfuric acid: 100 g/liter | Room | 1 |
| | | | temperature | |
| (B-7) | Water washing | | Room | 1 |
| | | | temperature | |
| (B-8) | Pre-dipping | THRU-CUP PED-104*²: 270 g/liter | Room | 2 |
| | | | temperature | |
| (B-9) | Activator | THRU-CUP PED-104*²: 270 g/liter | 30 | 8 |
| | | THRU-CUP AT-105*²: 30 ml/liter | | |
| (B-10) | Water washing | | Room | 1 |
| | | | temperature | |
| (B-11) | Accelerator (1) | THRU-CUP AL-106*²: 100 ml/liter | 25 | 3 |
| (B-12) | Water washing | | Room | 1 |
| | | | temperature | |
| (B-13) | Accelerator (2) | ALCUP MEL-3-A*²: 50 ml/liter | 25 | 1 |
| (B-14) | Electroless copper | THRU-CUP PEA bath*² | 33 | 20 |
| | plating | | | |
| (B-15) | Water washing | | Room | 2 |
| | | | temperature | |
| (B-16) | Drying | | | |

*²made by C. Uyemura & Co., Ltd.

TABLE 3

| | | | Temperature | Time |
|---|---|---|---|---|
| Treatment | | Chemicals used | (° C.) | (minutes) |
| (C-1) | Acidic cleaner | THRU-CUP | 40 | 5 |
| | | MSC-3-A*²: | | |
| | | 100 ml/liter | | |
| (C-2) | Hot-water washing | | 40 | 1 |
| (C-3) | Water washing | | Room | 1 |
| | | | temperature | |
| (C-4) | Acid washing | Sulfuric acid: | Room | 1 |
| | | 100 g/liter | temperature | |
| (C-5) | Water washing | | Room | 1 |
| | | | temperature | |
| (C-6) | Copper | Plating bath | Conditions | |
| | electroplating | indicated below | indicated below | |
| (C-7) | Water washing | | Room | 1 |
| | | | temperature | |
| (C-8) | Prevention of | THRU-CUP | Room | 1 |
| | discoloration | AT-21*²: | temperature | |
| | | 10 ml/liter | | |
| (C-9) | Waster washing | | Room | 1 |
| | | | temperature | |
| (C-10) | Drying | | | |

*²made by C. Uyemura & Co., Ltd.

### Composition of Copper Electroplating Bath [I]

Copper sulfate pentahydrate: 200 g/liter
Sulfuric acid: 50 g/liter
Chloride ion: 50 mg/liter
THRU-CUP EVF-2A*² (as an additive containing an S-containing compound): 2.5 ml/liter
THRU-CUP EVF-B*² (as an additive containing a polyether compound): 10 ml/liter
THRU-CUP EVF-T*² (as an additive containing an N-containing compound): 2 ml/liter
   *2: made by C. Uyemura & Co., Ltd.

### Copper Electroplating Conditions of Step (C-6)

### <Conditions 1-1 (Primary Plating)>

Copper electroplating bath: copper electroplating bath [I]

Cathode current density: 1.0 A/dm² (direct current)

Plating time: 60 minutes

Plating temperature: 25° C.

### <Conditions 2-1 (Secondary Plating)>

Copper electroplating bath: copper electroplating bath [I]

Plating conditions: indicated in Table 4

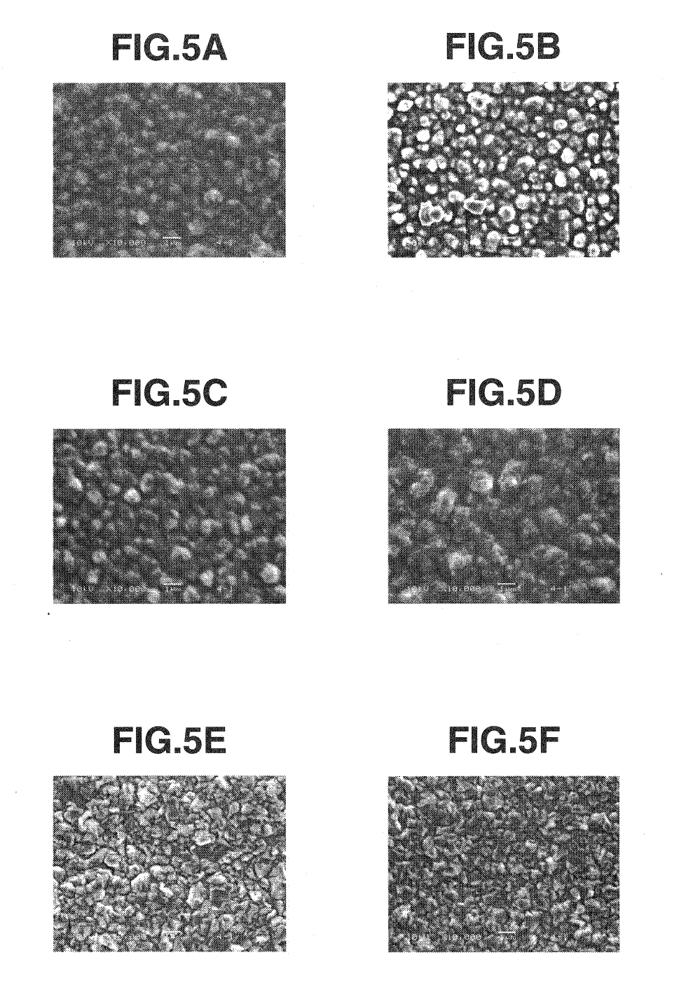

The resulting copper electroplating films were evaluated with respect to the surface roughness (Ra) and adhesion. The results are shown in Table 4. Moreover, the results of observation of the film surfaces of the copper electroplating films obtained in Experimental Examples 1 to 4 through a scanning electron microscope are, respectively, shown in FIGS. 5A to 5D.

### Evaluation Methods

Surface Roughness (Ra):
observed through a laser microscope (VK-8550, made by Keyence corporation)

Measurement of Adhesion Strength:
using a 18 mm wide adhesive tape pursuant to JIS Z 1522 and measured pursuant to “5.7 Peeling self-Strength” of JIS C 6481¹⁹⁹⁰.

### Peeling Test Of Copper:

a 18 mm wide self-adhesive tape pursuant to JIS Z 1522 was used. A fresh surface of the adhesive tape was bonded under pressure of a finger to a surface of a sample (copper electroplating film) by a length of 60 mm so that no bubbles were left, followed by quickly peeling the tape in a direction of a right angle to the plated surface after 10 seconds. The presence or absence of the plating film attached to the tape side was visually observed.

TABLE 4

| | | | Experimental Example | | | | | |
|---|---|---|---|---|---|---|---|---|
| | | | 1 | 2 | 3 | 4 | 5 | 6 |
| Reverse | Positive | Cathode current | 1 | 1 | 1 | 1 | 1 | 1 |
| Electrolysis | | density [A/dm²] | | | | | | |
| Pulse | | Pulse time [ms] | 30 | 30 | 30 | 30 | 30 | 30 |
| (secondary | Negative | Cathode current | 3 | 3 | 5 | 3 | 1.75 | 3 |
| plating) | | density [A/dm²] | | | | | | |
| | | Pulse time [ms] | 1 | 5 | 1 | 1 | 1 | 5 |

| | | | | | | |
|---|---|---|---|---|---|---|
| Treating time [minutes] | 1 | 5 | 5 | 5 | 5 | 20 |
| Plating temperature [° C.] | 25 | 25 | 25 | 25 | 25 | 25 |

| | | | | | | |
|---|---|---|---|---|---|---|
| Surface roughness (Ra) [μm] | 0.06 | 0.247 | 0.083 | 0.084 | 0.028 | 0.520 |
| Adherent copper on tape | no | no | no | no | no | no |
| Adhesion strength [gf/cm] | 123 | 152 | 121 | 119 | 85 | 148 |

### Experimental Examples 7 and 8

An FR-4 substrate was used as an object to be plated and copper electroplating films were formed according to the treating procedure indicated in the above Tables 1 to 3. The copper electroplating [step (C-6)] was carried out under the following conditions 1-1 (primary plating) and conditions 2-2 (secondary plating) in this order.

### Composition A of Copper Electroplating Bath [II]

Copper sulfate pentahydrate: 200 g/liter
Sulfuric acid: 50 g/liter
Chloride ion: 50 mg/liter
—(S—(CH₂)₃—SO₃Na)₂ (as an S-containing compound): 5 mg/liter
Polyethyleneimine #600 (as an N-containing compound): 1 mg/liter

### Composition B of Copper Electroplating Bath [II]

Copper sulfate pentahydrate: 100 g/liter
Sulfuric acid: 150 g/liter
Chloride ion: 50 mg/liter
Sodium 3-(benzothiazolyl-2-mercapto)-propylsulfonate (as an S and N-containing compound): 50 mg/liter

### Copper Electroplating Conditions of Step (C-6)

### <Conditions 1-1 (Primary Plating)>

Copper electroplating bath: copper electroplating bath [I]

Cathode current density: 1.0 A/dm² (direct current)

Plating time: 60 minutes

Plating temperature: 25° C.

### <Conditions 2-2 Secondary Plating)>

Copper electroplating bath: indicated in Table 5

Cathode current density: 3.0 A/dm² (direct current)

Plating time: 5 minutes

Plating temperature: 25° C.

The resulting copper electroplating films were evaluated in the same manner as in Experimental Example 1 with respect to the surface roughness (Ra) and adhesion. Moreover, the surfaces of the copper electroplating films obtained in Experimental Examples 7, 8 were observed through a scanning electron microscope, with the results shown in FIGS. 5E and 5F, respectively.

TABLE 5

Experimental Example

| | 7 | 8 |
|---|---|---|
| Copper electroplating bath [II] | Composition A | Composition B |
| for secondary plating | | |
| Surface roughness (Ra) [μm] | 0.06 | 0.247 |
| Adherent copper on tape | no | no |
| Adhesion strength [gf/cm] | 123 | 152 |

### Experimental Examples 9 and 10

An FR-4 substrate was used as an object to be plated, on which a copper electroplating film was formed according to the treating steps indicated in the afore-indicated Tables 1 to 3. The copper electroplating [step (C-6)] was performed under the following conditions 1-1 (primary plating) and conditions 2-3 (secondary plating) in this order.

### Copper Electroplating Conditions of Step (C-6)

### <Conditions 1-1 (Primary Plating)>

Copper electroplating bath: copper electroplating bath [I]

Cathode current density: 1.0 A/dm² (direct current)

Plating time: 60 minutes

Plating temperature: 25° C.

### <Conditions 2-3 (Secondary Plating)>

Copper electroplating bath: copper electroplating bath [I]

Plating conditions: indicated in Table 6

The resulting copper electroplating films were evaluated in the same manner as in Experimental Example 1 with respect to the surface roughness (Ra) and adhesion. The results are shown in Table 6.

TABLE 6

| | | | Experimental | |
|---|---|---|---|---|
| | | | Example | |
| | | | 9 | 10 |
| Reverse | Positive | Cathode current density | 1 | 1 |
| Electrolysis | | [A/dm²] | | |
| Pulse | | Pulse time [ms] | 30 | 15 |
| (secondary | Negative | Cathode current density | 4 | 3 |
| plating) | | [A/dm²] | | |
| | | Pulse time [ms] | 2 | 1 |

| | | |
|---|---|---|
| Treating time [minutes] | 5 | 5 |
| Plating temperature [° C.] | 25 | 25 |

| | | |
|---|---|---|
| Surface roughness (Ra) [μm] | 0.145 | 0.155 |
| Deposition of copper on tape | no | no |
| Adhesion [gf/cm] | 131 | 145 |

### Experimental Examples 11 and 12

An FR-4 substrate was used as an object to be plated, on which a copper electroplating film was formed according to the treating steps indicated in the afore-indicated Tables 1 to 3. The copper electroplating [step (C-6)] was performed under the following conditions 1-1 (primary plating) and conditions 2-4 (secondary plating) in this order.

### Copper Electroplating Conditions of Step (C-6)

### <Conditions 1-1 (Primary Plating)>

Copper electroplating bath: copper electroplating bath [I]

Cathode current density: 1.0 A/dm² (direct current)

Plating time: 60 minutes

Plating temperature: 25° C.

### <Conditions 2-4 (Secondary Plating)>

Copper electroplating bath: indicated in Table 7

Cathode current density: 3.0 A/dm² (direct current)

Plating time: 10 minutes

Plating temperature: 25° C.

The resulting electrolytic copper-plated films were evaluated in the same manner as in Experimental Example 1 with respect to the surface roughness (Ra) and adhesion. The results are shown in Table 7.

TABLE 7

Experimental Example

| | 11 | 12 |
|---|---|---|
| Copper electroplating bath [II] | Composition A | Composition B |
| for secondary plating | | |
| Surface roughness (Ra) [μm] | 0.482 | 0.33 |
| Adherent copper on tape | no | no |
| Adhesion strength [gf/cm] | 140 | 135 |

### Comparative Experimental Example 1

An FR-4 substrate was used as an object to be plated, on which a copper electroplating film was formed according to the treating steps indicated in the afore-indicated Tables 1 to 3. The copper electroplating [step (C-6)] was performed under the following conditions 1-1 (primary plating) alone.

### Copper Electroplating Conditions of Step (C-6)

### <Conditions 1-1 (Primary Plating)>

Copper electroplating bath: copper electroplating bath [I]

Cathode current density: 1.0 A/dm² (direct current)

Plating time: 60 minutes

Plating temperature: 25° C.

The surface roughness (Ra) and adhesion of the resulting copper electroplating film were evaluated in the same manner as in Experimental Example 1. The results are shown in Table 8.

TABLE 8

| | Comparative Experimental |
|---|---|
| | Example 1 |
| Surface roughness (Ra) [μm] | 0.021 |
| Adherent copper on tape | no |
| Adhesion strength [gf/cm] | 76 |

The comparison between Experimental Examples 1 to 12 and Comparative Experimental Example 1 reveals that the copper electroplating films whose surface are roughened according to the invention impart high adhesion. Moreover, the copper peeling test shows that no adherent copper is observed, revealing that the irregularities formed on the surface by the secondary plating do not become embrittled. In addition, it will be seen that when the secondary plating conditions are altered, roughened surfaces having various surface roughnesses (Ra) can be formed.

### Experimental Example 13

A SUS sheet was used as an object to be plated and a copper electroplating film was formed by the treating steps indicated in the foregoing Table 3. The copper electroplating [step (C-6)] was carried out under the following conditions 1-2 (primary plating) and conditions 2-5 (secondary plating) in this order.

### Copper Electroplating Conditions of Step (C-6)

### <Conditions 1-2 (Primary Plating)>

Copper electroplating bath: copper electroplating bath [I]

Cathode current density: 1.0 A/dm² (direct current)

Plating time: 110 minutes

Plating temperature: 25° C.

### <Conditions 2-5 (Secondary Plating)>

Copper electroplating bath: copper electroplating bath [I]

Plating conditions: indicated in Table 9

The resulting copper electroplating film was evaluated with respect to the film thickness, tension strength (tensile strength) and percentage elongation. The results are shown in Table 9.

### Evaluation Methods

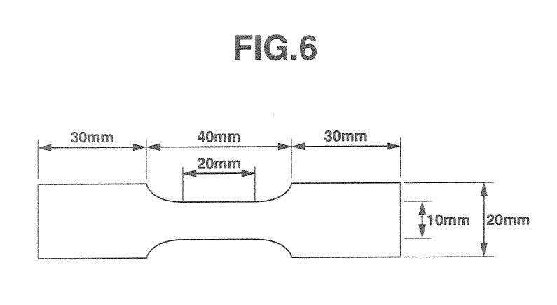

The plating film was peeled off from the SUS sheet while attention was paid so as not to damage the plating film, and was punched in such a form and size as shown in FIG. 6 thereby providing a test piece.
The thickness of the test piece at the central portion thereof was measured by means of a fluorescent X-ray film thickness gauge to give a plating film thickness of the test piece (d [mm]).
The tensile stress was measured under conditions of a chuck-chuck distance of 40 mm and a pulling rate of 4 mm/minute.
The tensile strength T [gf/mm] is obtained from a measured maximum tensile stress (F [gf]) and the plating film thickness of the test piece (d [mm]) according to the following equation.

T[gf/mm]=F[gf]/(10[mm]×d[mm])
The percentage elongation (E [%]) is obtained according to the following equation using an elongated length (ΔL [mm]) of the film from commencement of pulling of the test piece to breakage thereof. The figure of 20 [mm] in the following equation is a length (original length) prior to pulling of the uniform width portion at the center of the test piece.

Percentage elongation(E[%])=ΔL[mm]/20[mm]
For the measurement, there was used Autograph AGS-100D, made by Shimadzu Corporation.

TABLE 9

| | | | Experimental |
|---|---|---|---|
| | | | Example 13 |
| Reverse | Positive | Cathode current density [A/dm²] | 1 |
| Electrolysis | | Pulse time [ms] | 30 |
| Pulse | Negative | Cathode current density [A/dm²] | 3 |
| (secondary | | Pulse time [ms] | 1 |

| | | |
|---|---|---|
| plating) | Treating time [minutes] | 5 |
| | Plating temperature [° C.] | 25 |

| | |
|---|---|
| Film thickness in primary plating [μm] | 24 |
| Film thickness in secondary plating [μm] | 1 |
| Average (n = 6) tensile strength [kgf/mm²] | 32 |
| Percentage elongation [%] | 29 |

### Experimental Example 14

A SUS sheet was used as an object to be plated and a copper electroplating film was formed by the treating steps indicated in the foregoing Table 3. The copper electroplating [step (C-6)] was carried out under the following conditions 1-3 (primary plating) and conditions 2-6 (secondary plating) in this order.

### Copper Electroplating Conditions of Step (C-6)

### <Conditions 1-3 (Primary Plating)>

Copper electroplating bath: copper electroplating bath [I]

Cathode current density: 1.0 A/dm² (direct current)

Plating time: 58 minutes

Plating temperature: 25° C.

### <Conditions 2-6 (Secondary Plating)>

Copper electroplating bath: copper electroplating bath [I]

Plating conditions: indicated in Table 10

The resulting copper electroplating film was evaluated in the same manner as in Experimental Example 13 with respect to the film thickness, tension strength (tensile strength) and percentage elongation. The results are shown in Table 10.

TABLE 10

| | | | Experimental |
|---|---|---|---|
| | | | Example 14 |
| Reverse | Positive | Cathode current density [A/dm²] | 1 |
| Electrolysis | | Pulse time [ms] | 30 |
| Pulse | Negative | Cathode current density [A/dm²] | 3 |
| (secondary | | Pulse time [ms] | 1 |

| | | |
|---|---|---|
| plating) | Treating time [minutes] | 63 |
| | Plating temperature [° C.] | 25 |

| | |
|---|---|
| Film thickness in primary plating [μm] | 12.5 |
| Film thickness in secondary plating [μm] | 12.5 |
| Average (n = 6) tensile strength [kgf/mm²] | 36 |
| Percentage elongation [%] | 19 |

### Comparative Experimental Example 2

A SUS sheet was used as an object to be plated and a copper electroplating film was formed by the treating steps indicated in the foregoing Table 3. The copper electroplating [step (C-6)] was carried out under the following conditions 2-7 (secondary plating) alone.

### Copper Electroplating Conditions of Step (C-6)

### <Conditions 2-7 (Secondary Plating)>

Copper electroplating bath: copper electroplating bath [I]

Plating conditions: indicated in Table 11

The resulting copper electroplating film was evaluated in the same manner as in Experimental Example 13 with respect to the film thickness, tension strength (tensile strength) and percentage elongation. The results are shown in Table 11.

TABLE 11

| | | | Comparative |
|---|---|---|---|
| | | | Experimental |
| | | | Example 2 |
| Reverse | Positive | Cathode current density [A/dm²] | 1 |
| Electrolysis | | Pulse time [ms] | 30 |
| Pulse | Negative | Cathode current density [A/dm²] | 3 |
| (secondary | | Pulse time [ms] | 1 |

| | | |
|---|---|---|
| plating) | Treating time [minutes] | 125 |
| | Plating temperature [° C.] | 25 |

| | |
|---|---|
| Plated film thickness [μm] | 25 |
| Average (n = 6) tensile strength [kgf/mm²] | 37 |
| Percentage elongation [%] | 14 |

### Comparative Experimental Example 3

A SUS sheet was used as an object to be plated and a copper electroplating film was formed by the treating steps indicated in the foregoing Table 3. The copper electroplating [step (C-6)] was carried out under the following conditions 1-4 (primary plating) alone.

### Copper Electroplating Conditions of Step (C-6)

### <Conditions 1-4 (Primary Plating)>

Copper electroplating bath: copper electroplating bath [I]

Cathode current density: 1.0 A/dm² (direct current)

Plating time: 115 minutes

Plating temperature: 25° C.

The resulting copper electroplating film was evaluated in the same manner as in Experimental Example 13 with respect to the film thickness, tension strength (tensile strength) and percentage elongation. The results are shown in Table 12.

TABLE 12

| | Comparative |
|---|---|
| | Experimental Example 3 |
| Plated film thickness [μm] | 25 |
| Average (n = 6) tensile strength [kgf/mm²] | 33 |
| Percentage elongation [%] | 30 |

The comparison between Experimental Examples 13, 14 and Comparative Experimental Examples 2, 3 reveals that the percentage elongation of the electroplating film of Comparative Experimental Example 2 wherein the plating was performed all by the reverse electrolysis pulse is low, thus the plating film being low in ductility. Where the ductility of a film is low, the film suffers cracks during the course of a thermal treatment in a board manufacturing process. It has been found that if the percentage elongation in this evaluation is not less than 15%, especially not less than 20%, such a film is likely to cause cracks. In contrast, the percentage elongation of the electroplating film of Experimental Example 13 is such that the ductility of the plating film does not substantially lower, and is such a value as being equal to that of Comparative Example 3 wherein plating is performed by application of a direct current therethroughout.

### Example 1

A buildup circuit board was made according to a semi-additive method.

A copper clad FR-4 substrate (thickness of 0.4 mm) was coated thereon with an insulating resin (epoxy resin) for buildup, made by Ajinomoto Co., Inc., in a thickness of 70 μm, followed by curing at 150° C. for 20 minutes. Thereafter, a via hole having a diameter of φ 100 μm was formed by means of a laser oscillator.

Next, according to the treating steps (A-1 to A-9 and B-1 to B-16) indicated in the foregoing Tables 1, 2, a 0.7 μm thick electroless plating film was formed and annealed at 150° C. for 30 minutes. After formation of a plating resist (a negative photosensitive dry film photoresist of a water-soluble type), copper electroplating was carried out (the via hole and surface pattern were simultaneously plated by the copper electroplating). The copper electroplating was the same as in Experimental Example 2.

A circuit was formed and the resist was removed with a sodium hydroxide aqueous solution, followed by removal of an unnecessary electroless copper plating film by etching (treatment with a sulfuric acid/hydrogen peroxide etching solution) to form the circuit, followed by repeating twice the step of coating with an insulating resin for buildup (epoxy resin), made by Ajinomoto Co., Inc., in a thickness of 70 μm and curing at 150° C. for 20 minutes and subsequent steps, thereby making a circuit board wherein six-layer circuits were built up.

The adhesion between the circuit (copper electroplating film) and the insulating resin arranged adjacent to each other of the resulting circuit board was enough to withstand practical use.

### Example 2

A circuit board was made according to a subtractive method.

A copper-clad FR-4 substrate (thickness of 0.2 mm), made by Matsushita Electric Works, Ltd., was built up thereon with a resin (insulating resin) clad copper foil, made by Matsushita Electric Works, Ltd. Thereafter, a via hole having a diameter of φ 100 μm was formed by means of a laser oscillator.

Next, according to the treating steps (A-1 to A-9 and B-1 to B-16) indicated in the foregoing Tables 1, 2, a 0.7 μm thick electroless plated film was formed, followed by copper electroplating (the via hole and surface platings were simultaneously performed by the copper electroplating). The copper electroplating was same as in Experimental Example 3.

Next, an etching resist (a negative photosensitive dry film photoresist of a water-soluble type) was formed, followed by removal of an unnecessary copper electroplating film and electroless copper plating film by etching (by treatment with a copper (II) chloride etching solution) to form a circuit and removal of the resist with a sodium hydroxide aqueous solution. Thereafter, the step of building up the resin (insulating resin) clad copper foil (FR-4), made by Matsushita Electric Works, Ltd., and subsequent steps were repeated twice, thereby providing a circuit board wherein six-layer circuits were built up.

The adhesion between the circuit (copper electroplating film) and the insulating resin arranged adjacent to each other of the resulting circuit board was enough to withstand practical use.

### Example 3

A circuit board was made according to a semi-additive method.

A copper clad FR-4 substrate (thickness of 0.4 mm) was coated thereon with an insulating resin (epoxy resin) for buildup, made by Ajinomoto Co., Inc., in a thickness of 70 μm, followed by curing at 150° C. for 20 minutes. Thereafter, a via hole having a diameter of φ 100 μm was formed by means of a laser oscillator.

Next, according to the treating steps (A-1 to A-9 and B-1 to B-16) indicated in the foregoing Tables 1, 2, a 0.7 μm thick electroless plated film was formed and annealed at 150° C. for 30 minutes. After formation of a plated resist (a negative photosensitive dry film photoresist of a water-soluble type), copper electroplating was carried out (the via hole and surface pattern were simultaneously plated by the copper electroplating). The copper electroplating was the same as in Experimental Example 7.

A circuit was formed and the resist was removed with a sodium hydroxide aqueous solution, followed by removal of an unnecessary electroless copper plating film by etching (treatment with a sulfuric acid/hydrogen peroxide etching solution) to form a circuit, followed by repeating twice the step of coating with an insulating resin for buildup (epoxy resin), made by Ajinomoto Co., Inc., in a thickness of 70 μm and curing at 150° C. for 20 minutes and subsequent steps, thereby making a circuit board wherein six-layer circuits were built up.

The adhesion between the circuit (copper electroplating film) and the insulating resin arranged adjacent to each other of the resulting circuit board was enough to withstand practical use.

### Example 4

A circuit board was made according to a subtractive method.

A copper-clad FR-4 substrate (thickness of 0.2 mm), made by Matsushita Electric Works, Ltd., was built up thereon with a resin (insulating resin) clad copper foil, made by Matsushita Electric Works, Ltd. Thereafter, a via hole having a diameter of φ 100 μm was formed by means of a laser oscillator.

Next, according to the treating steps (A-1 to A-9 and B-1 to B-16) indicated in the foregoing Tables 1, 2, a 0.7 μm thick electroless plated film was formed, followed by copper electroplating (the via hole and surface platings were simultaneously performed by the copper electroplating). The copper electroplating was same as in Experimental Example 8.

Next, an etching resist (a negative photosensitive dry film photoresist of a water-soluble type) was formed, followed by removal of unnecessary copper electroplating film and electroless copper plating film by etching (by treatment with a copper (II) chloride etching solution) to form a circuit and removal of the resist with a sodium hydroxide aqueous solution. Thereafter, the step of building up the resin (insulating resin) clad copper foil (FR-4), made by Matsushita Electric Works, Ltd., and subsequent steps were repeated twice, thereby providing a circuit board wherein six-layer circuits were built up.

The adhesion between the circuit (copper electroplating film) and the insulating resin arranged adjacent to each other of the resulting circuit board was enough to withstand practical use.

1. A manufacturing method of a buildup circuit board comprising the steps of:
forming a wiring layer on a first organic polymer insulating layer by copper electroplating; and
further building up a second organic polymer insulating layer on said wiring layer, wherein
said copper electroplating comprises a first electroplating using a first copper electroplating bath and a second electroplating using a second copper electroplating bath for forming a roughened surface in the final step of the copper electroplating,
said first copper electroplating bath comprises a polyether compound,
said second copper electroplating bath comprises a sulfur-containing compound and a nitrogen-containing compound and is free of a polyether compound or comprises a sulfur and nitrogen-containing compound and is free of a polyether compound,
said sulfur-containing compound is selected from the group consisting of sulfur-containing compounds represented by the following formulas (1) to (3):
R₁—S—(CH₂)ₙ—(O)ₚ—SO₃M (1)
(R₂)₂N—CSS—(CH₂)ₙ—(CHOH)ₚ—(CH₂)ₙ—(O)ₚ—SO₃M (2)
R₂—O—CSS—(CH₂)ₙ—(CHOH)ₚ—(CH₂)ₙ—(O)ₚ—SO₃M (3)
wherein R₁ represents a hydrogen atom or a group represented by —(S)ₘ—(CH₂)ₙ—(O)ₚ—SO₃M, R₂'s independently represent an alkyl group having 1 to 5 carbon atoms, M represents a hydrogen atom or an alkali metal, m is 0 or 1, n is an integer of 1 to 8, and p is 0 or 1,
said nitrogen-containing compound is selected from the group consisting of polyethyleneimine, polyvinyl imidazole, polyvinyl alkylimidazoles, copolymers of vinyl pyrrolidone and vinyl alkylimidazoles and derivatives thereof, and janus green B,
said sulfur and nitrogen-containing compound selected from the group consisting of thiazole, thiazoline, benzothiazoline, rhodanine, benzothiazole and derivatives thereof, and methylene blue and titanium yellow, and
said second organic polymer insulating layer is formed directly on the roughened surface of said wiring layer.

2. The manufacturing method of a buildup circuit board according to claim 1, wherein said roughened surface has a surface roughness Ra of 0.01 to 1 mm.

3. The manufacturing method of a buildup circuit board according to claim 1, wherein a time where said electroplating using the second copper electroplating bath is applied is in the range of ⅓ to 1/100 relative to total time of said copper electroplating.

4. The manufacturing method of a buildup circuit board according to claim 1, wherein the wiring layer has a thickness of 5 to 40 mm.

5. The manufacturing method of a buildup circuit board according to claim 4, wherein said second electroplating using the second copper electroplating bath forms a thickness at not less than 0.1 mm and less than 5 mm.

6. The manufacturing method of a buildup circuit board according to claim 1, wherein said first copper electroplating bath further comprises a sulfur-containing compound and a nitrogen-containing compound,
said sulfur-containing compound is selected from the group consisting of sulfur-containing compounds represented by the following formulas (1) to (3):
R₁—S—(CH₂)ₙ—(O)ₚ—SO₃M (1)
(R₂)₂N—CSS—(CH₂)ₙ—(CHOH)ₚ—(CH₂)ₙ—(O)ₚ—SO₃M (2)
R₂—O—CSS—(CH₂)ₙ—(CHOH)ₚ—(CH₂)ₙ—(O)ₚ—SO₃M (3)
wherein R₁ represents a hydrogen atom or a group represented by
—(S)ₘ—(CH₂)ₙ—(O)ₚ—SO₃M, R₂'s independently represent an alkyl group having 1 to 5 carbon atoms, M represents a hydrogen atom or an alkali metal, m is 0 or 1, n is an integer of 1 to 8, and p is 0 or 1, and
said nitrogen-containing compound is selected from the group consisting of polyethyleneimine, polyvinyl imidazole, polyvinyl alkylimidazoles, copolymers of vinyl pyrrolidone and vinyl alkylimidazoles and derivatives thereof, and janus green B.

7. The manufacturing method of a buildup circuit board according to claim 1, wherein said first copper electroplating and second copper electroplating are carried out using a direct current.

8. The manufacturing method of a buildup circuit board according to claim 1, wherein said first copper electroplating is carried out using a direct current and said second copper electroplating is carried out using a reverse electrolysis pulse.

9. The manufacturing method of a buildup circuit board according to claim 8, wherein a time where said second electroplating using the reverse electrolysis pulse is applied is in the range of ⅓ to 1/100 relative to total time of said copper electroplating.

10. The manufacturing method of a buildup circuit board according to claim 1, wherein said second copper electroplating forms a thickness at not less than 1/50 and not larger than ½ relative to total thickness of the wiring layer.
